(19) United States
(12) Patent Application Publication
(10) Pub. No.: US 2007/0015430 A1
(43) Pub. Date: Jan. 18, 2007

(54) Method of manufacturing organic electroluminescent panel, organic electroluminescence device, and mask

(75) Inventors: Yoshitaka Nishio, Osaka (JP); Hiroshi Matsuki, Hashima-gun (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD., Osaka (JP)

(21) Appl. No.: 11/526,755

(22) Filed: Sep. 26, 2006

Related U.S. Application Data
(62) Division of application No. 10/378,667, filed on Mar. 5, 2003.

(30) Foreign Application Priority Data
Mar. 2, 2002 (JP) JP2002-059591

(51) Int. Cl. H01J 9/00

(52) U.S. Cl. 445/24

(57) ABSTRACT

An organic EL panel is provided, which is manufactured without scratching an organic layer. An organic luminescent layer is formed by evaporating an organic luminescent material over a hole injecting electrode by placing a mask used to evaporate a luminescent layer to be kept spaced apart from a substrate. By placing the mask while a bottom surface thereof is brought into contact with top surfaces of spacers, it is possible to space apart the mask from a hole transporting layer formed over the substrate.

### BACKGROUND OF THE INVENTION

1. Field of the Invention

The present invention relates to an organic electroluminescent device, a method of manufacturing an organic electroluminescent panel, and a mask used in a IL manufacturing sequence of the organic electroluminescent panel.

2. Description of the Related Art

An organic electroluminescent panel (hereinafter, also referred to as “organic EL panel”) is self-luminous and therefore has better visibility than a liquid crystal panel. Since it does not need a backlight, it can be a thin and light display panel. Hence, the organic EL panel attracts attention as a panel that will take over the liquid crystal panel in the near future. In general, an organic electroluminescent device (hereinafter, also referred to “organic EL device”) provided to the organic EL panel emits light through recombination of electrons injected from an electron injecting electrode to an electron transporting layer with holes injected from a hole injecting electrode to a hole transporting layer at the interface between the organic luminescent layer and the hole transporting layer or inside of the organic luminescent layer in the vicinity of the interface. A color organic EL panel is manufactured by forming organic luminescent layers of respective colors by evaporating organic materials emitting red, green, and blue light, respectively.

FIG. 1 is a view showing a conventional manufacturing sequence at a step of evaporating an organic luminescent layer. The drawing shows a state where a hole injecting electrode 12, an insulation layer 14, and a hole transporting layer 16 are formed in order on a substrate 10. According to the conventional evaporation step of the organic luminescent layer, a mono-color luminescent material is evaporated while the bottom surface of a mask 18 used to form an organic luminescent layer is brought into contact with the hole transporting layer 16, and then a luminescent material of another color is evaporated using the mask 18 in a different chamber. This step is generally referred to as the color-layer successive deposition step of luminescent materials. In the conventional color-layer successive deposition step, because the positioning is performed while the bottom surface of the mask 18 is brought into contact with the hole transporting layer 16, the mask 18 possibly scrapes the surface of the hole transporting layer 16 and leaves flaws 28. These flaws 28 cause a pin-hole in the electron injecting electrode formed in a latter film formation step, and gives rise to a dark spot defect.

### SUMMARY OF THE INVENTION

It is therefore an object of the invention to provide a method of manufacturing an organic EL panel, capable of solving the above problems and an organic EL device as well as a mask used in the manufacturing sequence of the organic EL panel.

The following description will describe means to achieve the above and other objects. Terms specifying the positional relations, such as “above,” “over,” “on,” and “beneath,” are used in the specification, and these terms are used, in connection with the positional relation of the substrate and a mask, on the assumption that the substrate is present at the lower side and the mask is present at the upper side relatively with respect to each other. Hence, for example, in a vacuum evaporation apparatus for resistance heating evaporation, the substrate may be held above the mask in term of spatial relations. Nevertheless, the specification describes the positional relation on the assumption that the substrate is at the lower side and the mask is at the upper side relatively with respect to each other for ease of explanation, and it is obvious to those skilled in the art that these terms are to be understood in light of the foregoing also in the appended claims.

In order to achieve the above and other objects, a method of manufacturing an organic electroluminescent panel according to one of aspects of the invention includes: forming a first electrode on a substrate; forming an organic luminescent layer over the first electrode by placing a mask to be kept spaced apart from a layer formed on the substrate; and forming a second electrode over the organic luminescent layer. The first electrode can be either a hole injecting electrode or an electron injecting electrode, and the second electrode can be either the electron injecting electrode or the hole injecting electrode. By spacing apart the mask from the layer formed on the substrate, it is possible to reduce a possibility that the mask scratches the layer formed on the substrate.

A method of manufacturing an organic electroluminescent panel according to another aspect of the invention includes: forming a first electrode on a substrate; forming spacers protruding in a direction perpendicular to a surface of the substrate; forming an organic luminescent layer over the first electrode by placing a mask while a surface thereof is brought into contact with the spacers; and forming a second electrode over the organic luminescent layer. By bringing the surface of the mask into contact with the spacers, it is possible to space apart the mask from the layer formed on the substrate, which can reduce a possibility that the mask scratches the layer formed on the substrate.

The forming spacers may include forming spacers each having a slope inclined gently downward. For example, the forming spacers may include: applying a resist material over the substrate; etching the resist material applied so that a part of the resist material is left at an outside of a luminescent region on the substrate; and allowing the resist material left to undergo reflow through heat treatment.

A method of manufacturing an organic electroluminescent panel according to still another aspect of the invention includes: forming a first electrode on a substrate; forming an organic luminescent layer over the first electrode by placing a mask, which has spacers protruding in a direction perpendicular to a surface of thereof, above the substrate; and forming a second electrode over the organic luminescent layer. The spacers provided to the mask allow a mask main body on which is formed a specific pattern to be spaced apart from the layer formed on the substrate, which can reduce a possibility that the mask main body scratches the layer formed on the substrate. The spacers and the mask main body may be made of a same material. By making the spacers and the mask main body from the same material, a used mask can be readily recycled. For example, in a case where the mask main body is made of a nickel material containing cobalt, a used mask can be readily recycled by forming the spacers also from the nickel material containing cobalt through an etching technique or a plating technique.

A mask according to still another aspect of the invention is a mask used to form an organic luminescent layer during a manufacturing sequence of an organic electroluminescent panel. The mask includes a mask main body on which a specific pattern is formed, and spacers protruding in a direction perpendicular to a surface of the mask main body, and the spacers and the mask main body are made of a same material. By forming the mask main body and the spacers from the same material, the mask main body and the spacers can be melted together without the need of separation when a used mask is melted to be recycled.

An organic electroluminescent device according to still another aspect of the invention includes: a first electrode formed on a substrate; spacers protruding in a direction perpendicular to a surface of the substrate at an outside of a luminescent region on the substrate; an organic luminescent layer formed over the first electrode within the luminescent region on the substrate; and a second electrode formed over the organic luminescent layer. In the evaporation step of the organic luminescent layer, the spacers are formed to protrude upward above the substrate for the mask to be placed on the top surfaces thereof. After the luminescent layer is evaporated, the spacers may protrude from a lamination structure on the substrate, or may be present within the lamination structure while protruding upward. The luminescent region means a region where the organic luminescent layer is formed, and the region at the outside of the luminescent region includes a region at the outside of the panel region where no organic EL device is formed. Also, the region at the outside of the luminescent region may include a region where no organic luminescent layer is formed within the panel region.

A method of manufacturing an organic electroluminescent panel according to still another aspect of the invention includes: forming a first electrode within each of a plurality of panel regions on a substrate; forming spacers protruding in a direction perpendicular to a surface of the substrate; forming an organic luminescent layer over the first electrode by placing a mask while a surface thereof is brought into contact with the spacers; forming a second electrode over the organic luminescent layer; and dividing the substrate into the respective panel regions. According to this manufacturing method, it is possible to manufacture a plurality of organic EL panels from a single substrate.

An organic electroluminescent device according to still another aspect of the invention includes: a first electrode formed within each of a plurality of panel regions on a substrate; spacers protruding in a direction perpendicular to a surface of the substrate at an outside of luminescent regions on the substrate; an organic luminescent layer formed over the first electrode within each of the luminescent regions on the substrate; and a second electrode formed over the organic luminescent layer. In the evaporation step of the organic luminescent layer, the spacers are formed to protrude upward above the substrate for the mask to be placed on the top surfaces thereof. After the luminescent layer is evaporated, the spacers may protrude from a lamination structure on the substrate, or may be present within the lamination structure while protruding upward. The luminescent region means a region where the organic luminescent layer is formed, and the region at the outside of the luminescent region includes a region at the outside of the panel region where no organic EL device is formed. Also, the region at the outside of the luminescent region may include a region where no organic luminescent layer is formed within the panel region.

It is to be noted that any arbitrary combination of the above-described structural components, and expressions changed between a method, an apparatus, a system and so forth are all effective as and encompassed by the present embodiments.

Moreover, this summary of the invention does not necessarily describe all necessary features so that the invention may also be sub-combination of these described features.

### BRIEF DESCRIPTION OF THE DRAWINGS

FIG. 1 is a view showing a conventional manufacturing sequence at a step of evaporating an organic luminescent layer;

FIG. 2A is a view showing a state where a hole injecting electrode is formed within a panel region on a substrate;

FIG. 2B is a view showing a state where spacers protruding in a direction perpendicular to the surface of the substrate are formed;

FIG. 2C is a view showing a state where a hole transporting layer is formed;

FIG. 3A is a view showing a state where an organic luminescent layer is formed;

FIG. 3B is a view showing a state where an electron transporting layer and an electron injecting electrode are formed;

FIG. 4A is a view showing one example of the shape and the layout of the spacers;

FIG. 4B is a side view of the substrate;

FIG. 4C is a view showing a state where a mask is placed while the bottom surface thereof is brought into contact with the spacers;

FIG. 5 is a view showing another example of the shape and the layout of the spacers;

FIG. 6 is a view showing a state where spacers are formed within the panel region on the substrate;

FIG. 7 is a view showing a state where an organic layer is evaporated using the spacers shown in FIG. 6;

FIG. 8A is a view showing a state where a resist material is applied on an insulation layer on the substrate through spin-coating;

FIG. 8B is a view showing a state where a part of the applied resist material is subjected to exposure and development;

FIG. 8C is a view showing a state where the remaining resist material is allowed to undergo reflow through heat treatment;

FIG. 9A is a view showing a state where a hole injecting electrode, an insulation layer, and a hole transporting layer are formed within a panel region on a substrate;

FIG. 9B is a view showing a state where an organic luminescent layer is formed over the hole injecting electrode;

FIG. 9C is a view showing a state where an electron transporting layer and an electron injecting electrode are formed over the organic luminescent layer;

FIG. 10A is a view showing one example of the shape and the layout of spacers;

FIG. 10B is a side view of a mask:

FIG. 10C is a view showing a state where a mask is placed while the spacers are brought into contact with the top surface of a lamination structure on the substrate; and

FIG. 11 is a view showing another example of the shape and the layout of the spacers.

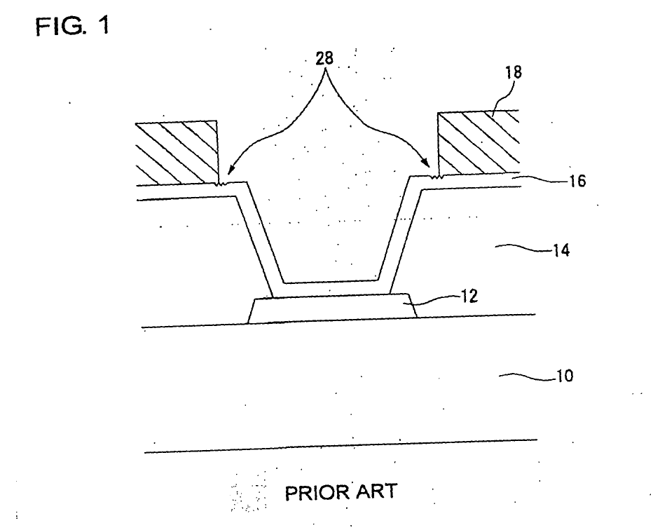

### DETAILED DESCRIPTION OF THE INVENTION

The invention will now be described based on preferred embodiments which do not intend to limit the scope of the present invention but exemplify the invention. All of the features and the combinations thereof described in the embodiments are not necessarily essential to the invention.

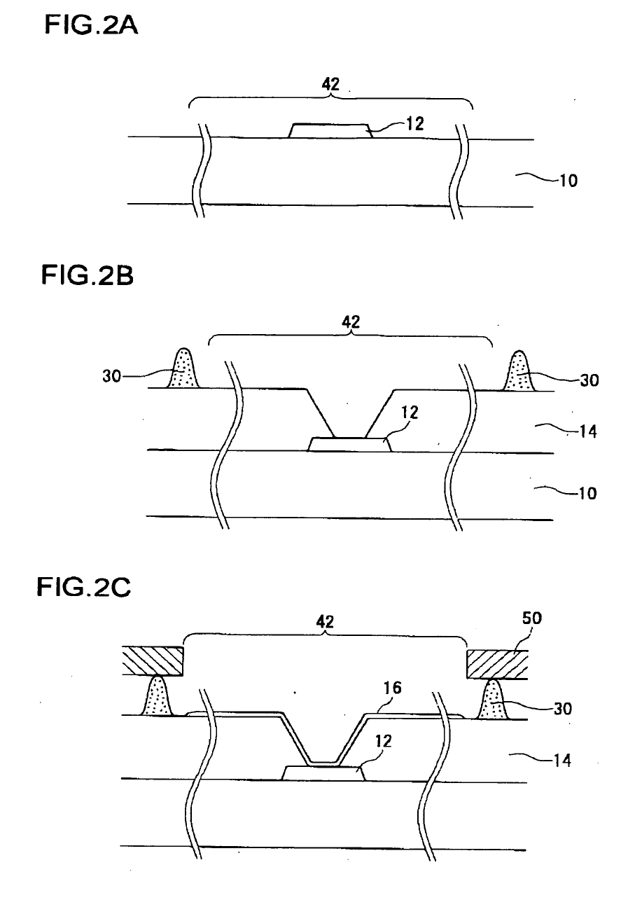

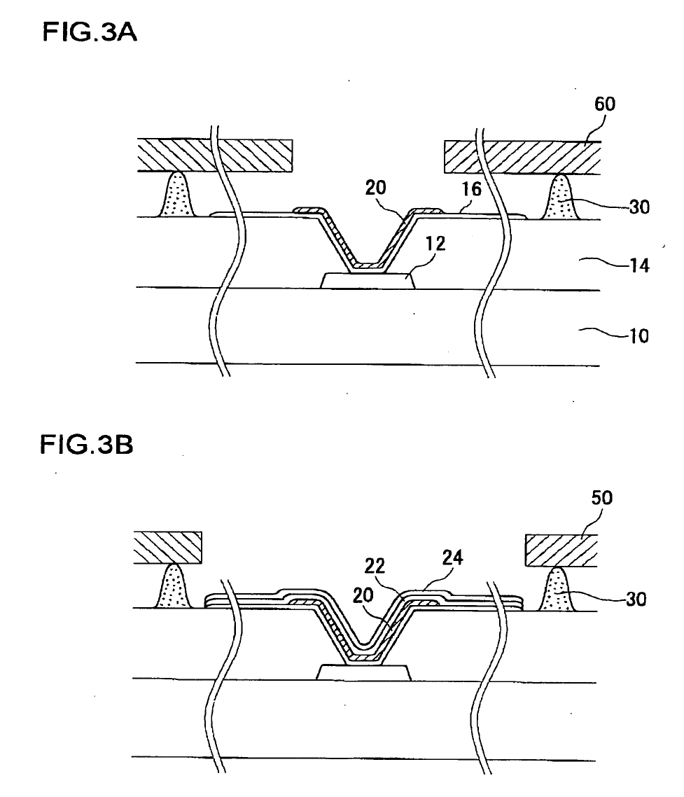

FIG. 2A through FIG. 2C and FIG. 3A through FIG. 3B are views showing the manufacturing sequence of an organic EL panel according to a first embodiment of the invention. FIG. 2A is a view showing a state where a hole injecting electrode 12 is formed within a panel region 42 on a substrate 10. The panel region 42 referred to herein means a region where an organic EL device will be formed on the substrate 10. The substrate 10 may be a glass substrate on which a thin film transistor (TFT) is formed as a switching element. In a case where a plurality of organic EL panels are manufactured from a single substrate 10, a plurality of panel regions 42 are present on the substrate 10. The hole injecting electrode 12 is made of indium tin oxide (ITO) FIG. 2A shows only one hole injecting electrode 12 for one pixel configuration. It should be appreciated, however, that as many hole injecting electrodes 12 as the pixels of the organic EL panel are actually formed in each panel region 42 at their respective predetermined positions.

FIG. 2B is a view showing a state where spacers 30 protruding in a direction perpendicular to the surface of the substrate 10 are formed. In this step, an insulation layer 14 is formed by applying a resist material on the substrate 10 first, and then by transferring a specific pattern such that exposes the hole injecting electrode 12 through exposure followed by development. Then, the spacers 30 protruding upward above the substrate 10 are formed at the outside of the panel region 42. A plurality of spacers 30 are provided at the outside of the panel region 42 to place a mask, and it is preferable that each has substantially an equal height. In this example, the spacers 30 are formed on the insulation layer 14. It should be appreciated, however, that the spacers 30 may be formed directly on the substrate 10 in another example. It is preferable to perform the step of forming the spacers 30 before an organic layer is evaporated.

FIG. 2C is a view showing a state where a hole transporting layer 16 is formed. In this step, the hole transporting layer 16 is formed by evaporating N,N′-di(naphthalene-1-yl)-N,N′-diphenyl-benzidine by placing a mask 50 for overall film formation to be brought into contact with the top surfaces of the spacers 30.

FIG. 3A is a view showing a state where an organic luminescent layer 20 is formed. In this step, the organic luminescent layer 20 is formed by evaporating an organic luminescent material over the hole injecting electrode 12 while a mask 60 used to form a luminescent layer is kept spaced apart from the layer formed on the substrate 10. By placing the mask 60 while the bottom surface thereof is brought into contact with the top surfaces of the spacers 30, it is possible to space apart the mask 60 from the hole transporting layer 16 over the substrate 10. In order to enable color display of the organic EL panel, the mask 60 is prepared for each of the colors including red, green, and blue, and the organic luminescent layers 20 of the respective colors are formed in different chambers. It is necessary to fine-tune the position of the mask 60 during this color-layer successive deposition step. However, by performing the positioning while the mask 60 is spaced apart from the substrate 10, it is possible to reduce a possibility that the mask 60 scratches the hole transporting layer 16.

FIG. 3B is a view showing a state where an electron transporting layer 22 and an electron injecting electrode 24 are formed. In this step, the electron transporting layer 22 may be formed commonly on the red, green, and blue organic luminescent layers 20 through the use of the mask 50 for overall film formation, or alternatively, it may be formed separately on the organic luminescent layers 20 of the respective colors. In the case of forming the electron transporting layer 20 for each color, as shown in FIG. 3A, a mono-color organic luminescent layer 20 is formed using the mask 60, and the electron transporting layer 22 is evaporated on the organic luminescent layer 20 thus formed, after which an organic luminescent layer 20 of another color and the electron transporting layer 22 therefor are formed in a different chamber. After the electron transporting layer 22 is formed, the electron injecting electrode 24 is formed over the organic luminescent layers 20 using the mask 50 for overall film formation. In a case where a plurality of panel regions are present on a single substrate 10, the respective panel regions are separated, and a lamination structure, that is, an organic EL device, is covered with a sealing body. An organic EL panel is thus manufactured.

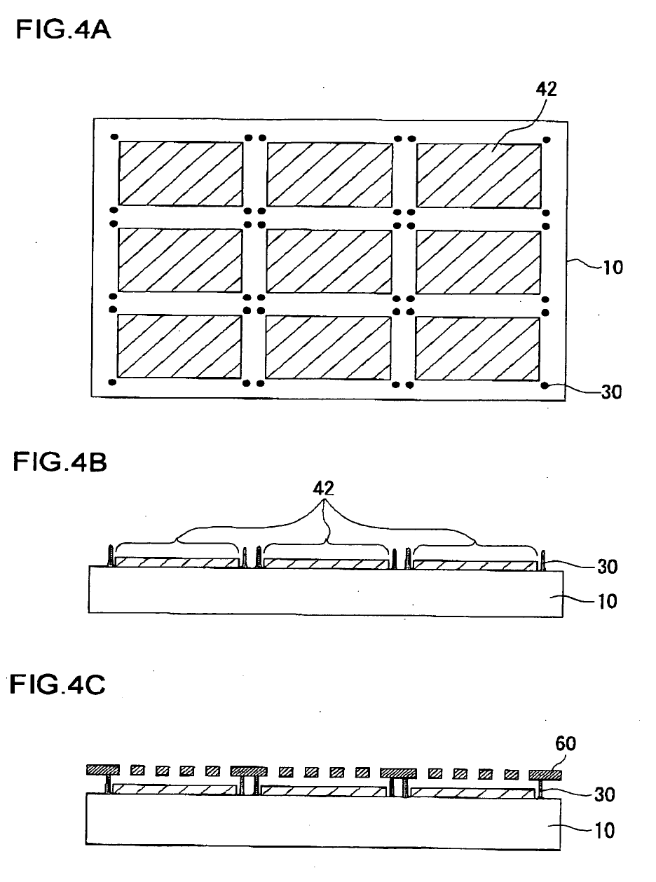

FIG. 4A is a view showing one example of the shape and the layout of the spacers 30. Herein, 3×3 panel regions 42 are provided on the substrate 10, and a plurality of spacers 30 are placed at the outside of the panel regions 42 on the periphery of the respective panel regions 42. In a case where the mask 50 is placed above the substrate 10 in terms of spatial relations within the evaporation apparatus, it is preferable to place the plurality of spacers 30 at adequately close intervals, so that the mask 50 will not cause deflection when placed thereon. In this example, the spacers 30 are located at positions corresponding to the four corners of the panel region 42 at the outside of the respective panel regions 42.

FIG. 4B is a view showing a side surface of the substrate 10. The drawing shows a state where the spacers 30 protruding in a direction perpendicular to the surface of the substrate 10 are provided at the outside of the panel regions 42. It is preferable that the spacers 30 are formed to be higher than the organic luminescent layer to be formed. In general, it is sufficient to form the spacers 30 in a height of approximately 3 to 5 μm.

FIG. 4C is a view showing a state where the mask 60 is placed while the bottom surface thereof is brought into contact with the spacers 30. Since the organic layer formed on the panel regions 42 will not come in contact with the mask 60, it is possible to reduce a possibility that the mask 60 scratches the organic layer at the positioning.

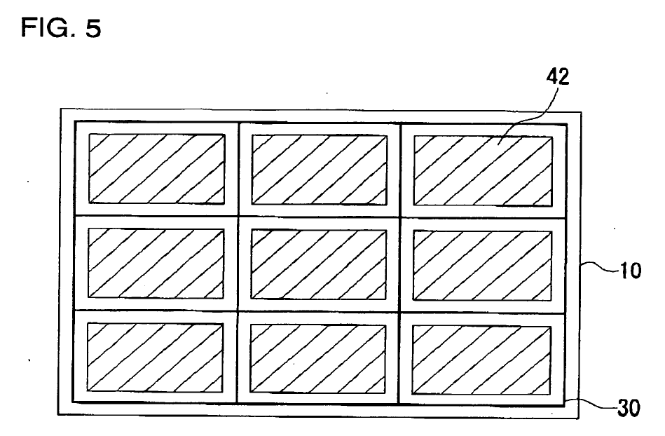

FIG. 5 is a view showing another example of the shape and the layout of the spacers 30. In this example, the spacers 30 are formed linearly at the outside of the panel regions 42 to enclose the respective panel regions 42. It should be noted, however, that the shapes and the layouts of the spacers 30 shown in FIG. 4A through FIG. 4C and FIG. 5 are for illustrative purpose only, and it is to be understood by those skilled in the art that various modifications are available.

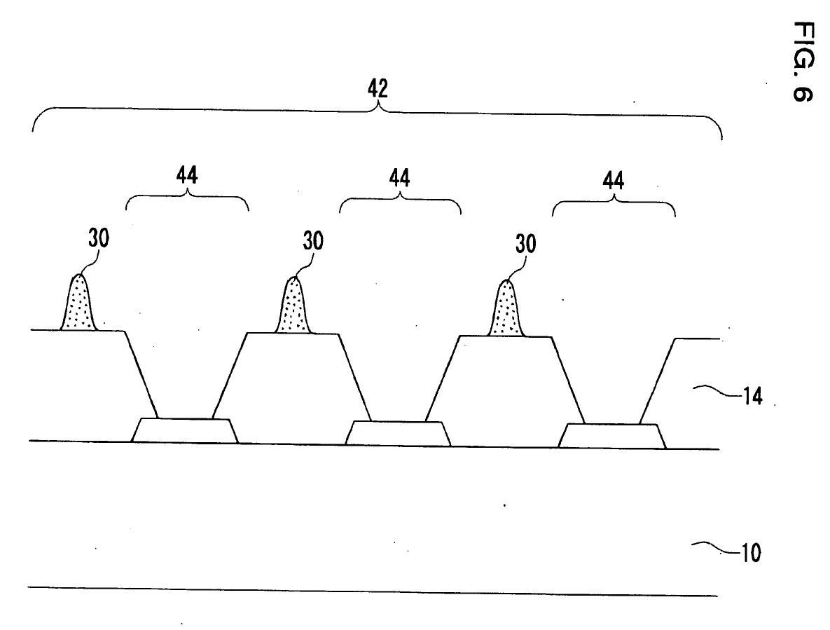

FIG. 6 is a view showing a state where the spacers 30 are formed within the panel region 42 on the substrate 10. Within the panel region 42 are luminescent regions 44 on which the organic luminescent layers are to be evaporated, and therefore, it is preferable to form the spacers 30 on the insulation layer 14 at the outside of the luminescent regions 44 so as not interfere with emission of light. The spacers 30 may be formed for the respective pixels within the panel region 42, or provided at adequate intervals. The spacers 30 may be formed directly on the substrate 10.

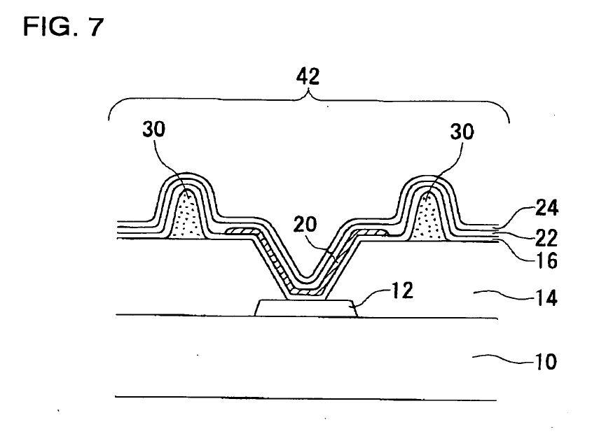

FIG. 7 is a view showing a state where an organic layer is evaporated using the spacers 30 shown in FIG. 6. In the case of overall film formation, a mask is placed on the spacers 30 at the outside of the panel region 42, and an organic material is then evaporated. In the color-layer successive deposition step of the organic luminescent layers, the organic luminescent layers 20 of respective colors are formed by positioning the mask placed on the spacers 30 at both the inside and outside of the panel region 42 and evaporating a mono-color organic luminescent material, and successively by positioning the mask and evaporating an organic luminescent material of another color in a different chamber.

As shown in the drawing, organic layers are laminated on the spacers 30 within the panel region 42 during the overall film formation step. In this example, the hole transporting layer 16, the electron transporting layer 22, and the electron injecting electrode 24 are formed on the spacers 30. For this reason, in a case where the spacers 30 have a sharp edge, the coverage is deteriorated, and a pin-hole may possibly occur in the uppermost electron injecting electrode 24. In order to avoid such an inconvenience, it is preferable that the spacers 30 have slopes gently inclined downward so that the organic layers are formed in a satisfactory manner.

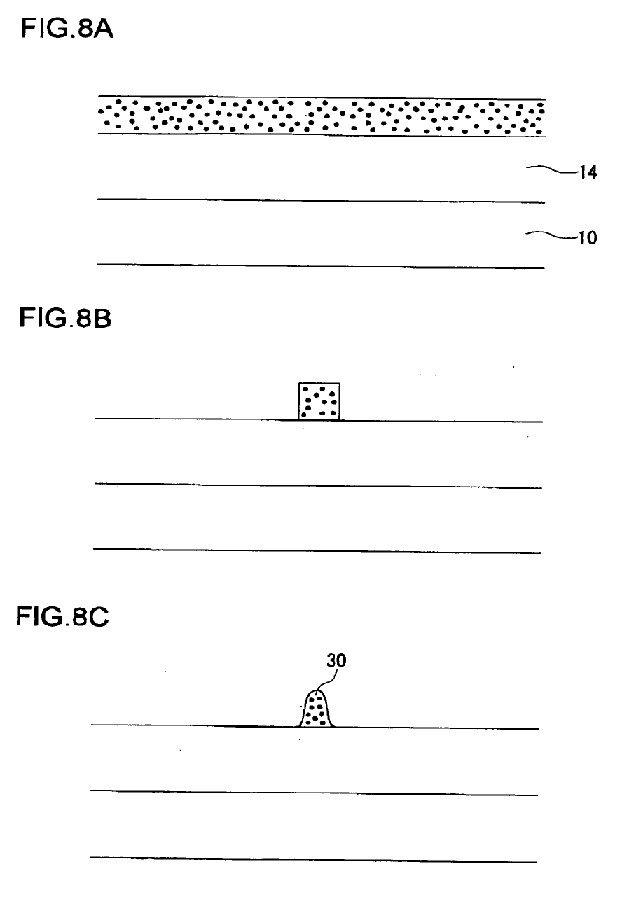

FIG. 8A through FIG. 8C are views showing the steps of forming the spacer 30 protruding in a direction perpendicular to the surface of the substrate 10. As shown in FIG. 8A, a resist material is applied on the insulation layer 14 on the substrate 10 by spin-coating. The resist material can be a photosensitive material, such as acrylic resin, or the same material as that of the insulation layer 14. Subsequently, as shown in FIG. 8B, the applied resist material is subjected to exposure and development so that a part of the resist material will be left at a predetermined position at the outside of the luminescent region. Then, as shown in FIG. 8C, the resist material thus left is allowed to undergo reflow through heat treatment. By allowing the resist material to undergo reflow, it is possible to form the spacer 30 having a slope gently inclined downward. In particular, in the case of forming the spacers 30 within the panel region, it is preferable to shape the spacer 30 to widen toward the end in order to form the organic layers, such as the hole transporting layer 16, on the spacers 30 in a satisfactory manner. In the case of forming the spacers 30 at the outside of the panel regions, it is also possible to reduce a possibility that the spacer 30 is scraped by the mask by forming the spacer 30 into a stable shape such that widens toward the end. In this example, the spacer 30 is formed by applying the resist material on the insulation layer 14; however, it is also possible to form the spacer 30 by subjecting the insulation layer 14 itself to exposure and development.

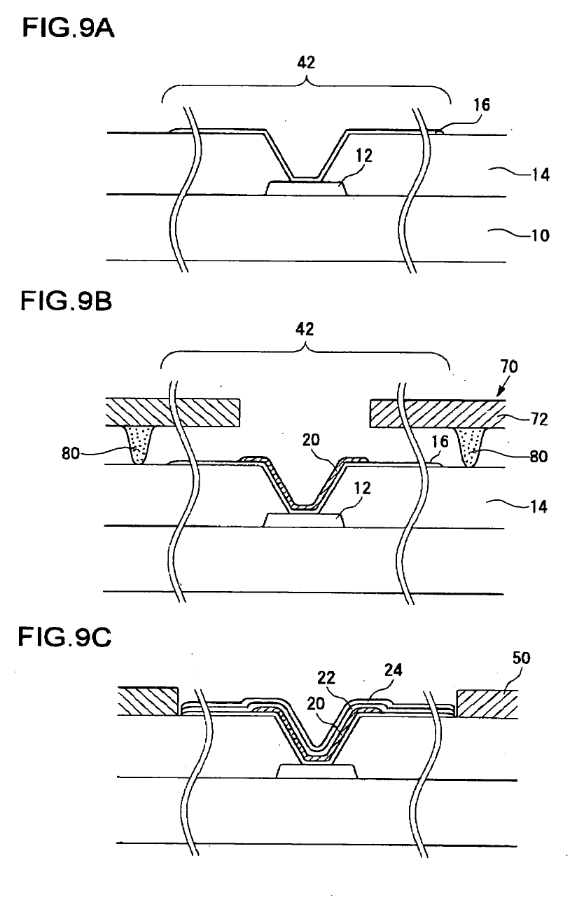

FIG. 9A through FIG. 9C are views showing the manufacturing sequence of an organic EL panel according to a second embodiment of the invention. FIG. 9A is a view showing a state where a hole injecting electrode 12, an insulation layer 14, and a hole transporting layer 16 are formed within a panel region 42 on the substrate 10.

FIG. 9B is a view showing a state where an organic luminescent layer 20 is formed over the hole injecting electrode 12. In this step, a mask 70 is used, which includes a mask main body 72 on which a specific pattern is formed, and spacers 80 protruding in a direction perpendicular to the surface of the mask main body 72. The organic luminescent layer 20 is formed on the hole injecting electrode 12 and the hole transporting layer 16 by placing the mask main body 72 above the substrate 10 while the bottom surfaces of the spacers 80 are brought into contact with the insulation layer 14. In the color-layer successive deposition step of the organic luminescent layers 20, since the mask main body 72 is placed to be spaced apart from the substrate 10, the mask main body 72 will not scratch the hole transporting layer 16 formed over the substrate 10 at the positioning of the mask 70.

FIG. 9C is a view showing a state where an electron transporting layer 22 and an electron injecting electrode 24 are formed on the organic luminescent layer 20. The electron transporting layer 22 may be formed for each color of the organic luminescent layers 20 through the use of the mask 70 of FIG. 9B. The electron injecting electrode 24 is formed through the use of a mask 50 for overall film formation. The mask 50 can be a mask having no spacers 80 as shown in the drawing. However, it may have the spacers 80 as the mask 70 shown in FIG. 9B.

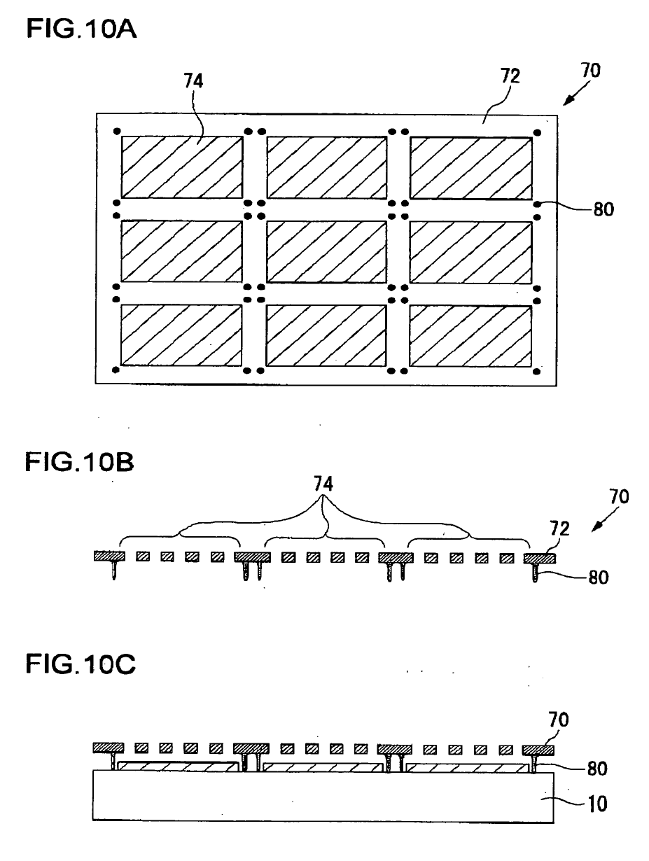

FIG. 10A is a view showing one example of the shape and the layout of the spacers 80. Herein, 3×3 mask regions 74 are provided on the mask main body 72, and a specific pattern is formed in each mask region 74. On the mask main body 72, a plurality of spacers 80 are placed at the outside of the respective mask regions 74 on the periphery. In a case where the mask 70 is placed above the substrate 10 in terms of spatial relations within the evaporation apparatus, it is preferable to place the plurality of spacers 80 at adequately close intervals, so that the mask main body 72 will not cause deflection when placed thereon. In this example, the spacers 80 are located at the positions corresponding to the four corners of the mask region 74 at the outside of the respective mask regions 74. It is preferable to form the spacers 80 and the mask main body 72 from the same material. By so doing, when the used mask 70 is melted to be recycled, the mask main body 72 and the spacers 80 can be melted together without the need of separation.

FIG. 10B is a view showing a side surface of the mask 70. The drawing shows a state where the spacers 80 protruding in a direction perpendicular to the surface of the mask main body 72 are provided at the outside of the mask regions 74. It is preferable that the spacers 80 are formed in a height such that the surface of the mask main body 72 will not come in contact with the already formed organic luminescent layer in the case of evaporating the organic luminescent layers of plural colors.

FIG. 10C is a view showing a state where the mask 70 is placed while the spacers 80 are brought into contact with the top surface of the lamination structure on the substrate 10. In the example shown in FIG. 9B, the spacers 80 come in contact with the top surface of the insulation layer 14. Since the organic layers formed in the panel regions on the substrate 10 will not come in contact with the mask main body 72, it is possible to reduce a possibility that the mask main body 72 scratches the organic layer at the positioning of the mask 70.

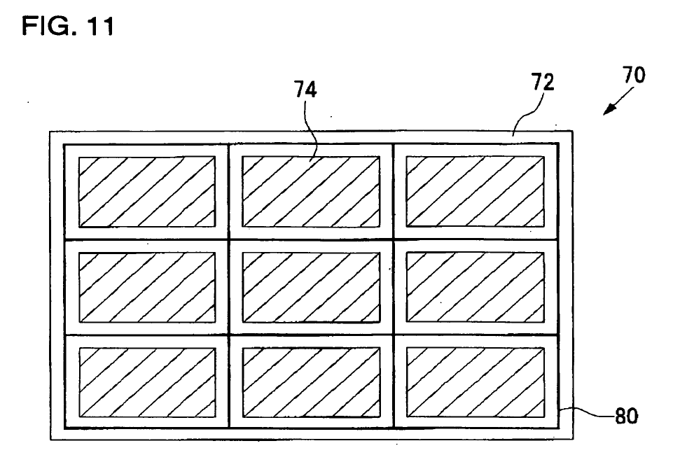

FIG. 11 is a view showing another example of the shape and the layout of the spacers 80. In this example, the spacers 80 are formed linearly at the outside of the mask regions 74 to enclose the respective mask regions 74. It should be noted, however, that the shapes and the layouts of the spacers 80 shown in FIG. 10A through FIG. 10C and FIG. 11 are for illustrative purpose only, and it is to be understood by those skilled in the art that various modifications are available.

While preferred embodiments of the invention have been described, it is to be understood that the technical scope of the invention is not limited to the description in the above. The embodiments above are given solely by way of illustration. It will be understood by those skilled in the art that various modifications may be made to combinations of the foregoing components and processes, and all such modified examples are also intended to fall within the scope of the invention.

For example, the embodiments above described the color-layer successive deposition step for forming organic luminescent layers of respective colors in different chambers using a plurality of masks. However, the methods of manufacturing the organic EL panel according the embodiments above are not limited to the above description, and a step of forming organic luminescent layers using a single mask may be included instead. In addition, although the embodiments above described specific materials of the organic layers to be evaporated by way of example, it is to be understood by those skilled in the art that the specified materials are given solely by way of illustration. Furthermore, a mask may be made of magnetic materials. In this case, the mask may be attracted by an electro magnet provided at a back side of a substrate so that the mask may be fixed to the substrate.

1. (canceled)

2. A method of manufacturing an organic electroluminescent panel, the method including:
forming a first electrode on a substrate;
forming spacers protruding in a direction perpendicular to a surface of the substrate, wherein the spacers have slopes so as to be progressively widened toward the end from the top of thereof;
forming an organic luminescent layer over the first electrode by placing a mask while a surface thereof is brought into contact with the spacers; and
forming a second electrode over the organic luminescent layer,
wherein the forming spacers includes:
applying a resist material over the substrate;
etching the resist material applied so that a part of the resist material is left at an outside of a luminescent region on the substrate; and
allowing the resist material left to undergo reflow through heat treatment.

3-4. (canceled)

5. A method of manufacturing an organic electroluminescent panel according to claim 2, wherein each spacer has substantially an equal height.

6. A method of manufacturing an organic electroluminescent panel, the method including:
forming a first electrode on a substrate;
forming an organic luminescent layer over the first electrode by placing a mask, which has spacers protruding in a direction perpendicular to a surface of thereof, above the substrate; and
forming a second electrode over the organic luminescent layer.

7. A method of manufacturing an organic electroluminescent panel according to claim 6, wherein the spacers and a mask main body are made of a same material.

8. A method of manufacturing an organic electroluminescent panel according to claim 7, wherein each spacer has substantially an equal height.

9-12. (canceled)

13. A method of manufacturing an organic electroluminescent panel, the method including:
forming a first electrode within each of a plurality of panel regions on a substrate;
forming spacers protruding in a direction perpendicular to a surface of the substrate;
forming an organic luminescent layer over the first electrode by placing a mask while a surface thereof is brought into contact with the spacers;
forming a second electrode over the organic luminescent layer; and
dividing the substrate into the respective panel regions.

14. (canceled)

15. A method of manufacturing an oranic elecrtroluminescent panel, the method including:
forming, within each of a plurality of panel regions on a substrate, first electrodes corresponding to a plurality of luminescent regions;
forming spacers protruding in a direction perpendicular to a surface of the substrate within the panel regions and outside of the luminescent regions, and forming spacers for respective panel regions so as to protrude in a direction perpendicular to the surface of the substrate outside of the panel regions;
placing a mask corresponding to the luminescent regions so that a surface of the mask is in contact with at least one of the spacers within the panel regions, and successively depositing organic luminescent layers for a plurality of colors above the first electrodes;
placing a mask corresponding to the panel regions so that a surface of the mask is in contact with at least one of the spacers outside of the panel regions, and forming a hole transporting layer or an electron transporting layer in the entirety of the each of the panel regions;
forming a second electrode over the hole transporting layer or the electron transporting layer; and
dividing the substrate into the respective panel regions.

16. A method of manufacturing an organic electroluminescent panel, the method including:
forming, within a panel region on a substrate, first electrodes corresponding to a plurality of luminescent regions;
forming spacers protruding in a direction perpendicular to a surface of the substrate within the panel region on the substrate;
placing a mask so that a surface of the mask is in contact with at least one of the spacers within the panel region, and successively depositing organic luminescent layers for a plurality of colors above the first electrodes;
forming a hole transporting layer or an electron transporting layer in the entirety of the panel region including the spacers; and
forming an electrically continuous second electrode over the hole transporting layer or the electron transporting layer in the entirety of the panel region.

17. The method of manufacturing an organic electroluminescent panel according to claim 15, wherein the forming of spacers forms the spacers by subjecting a resist material applied to the substrate to exposure and development so that a part of the resist material will be left at a predetermined position.

18. The method of manufactured an organic electroluminescent panel according to claim 16, wherein the forming of spacers forms the spacers by subjecting a resist material applied to the substrate to exposure and development so that a part of the resist material will be left at a predetermined position.
